(19) United States
(12) Patent Application Publication
(10) Pub. No.: US 2025/0043417 A1
(43) Pub. Date: Feb. 6, 2025

(54) CONFIGURABLE SOURCE

(71) Applicant: ULTRA CLEAN HOLDINGS, INC., Hayward, CA (US)

(72) Inventors: Michael RAMACCIOTTI, Fremont, CA (US); Alan CAMYRE, Vail, AZ (US); Jon HYLBERT, San Jose, CA (US); Genaro RODRIGUEZ, San Jose, CA (US); Hyeon LEE, Georgetown, TX (US); Ed MANDEL, Castro Valley, CA (US)

(21) Appl. No.: 18/792,309

(22) Filed: Aug. 1, 2024

Related U.S. Application Data
(60) Provisional application No. 63/517,807, filed on Aug. 4, 2023.

(51) Int. Cl. C23C 16/448; C23C 16/52

(52) U.S. Cl. CPC C23C 16/448; C23C 16/52

(57) ABSTRACT

A gas source includes a single tray or a plurality of trays including a top cover and a bottom cover, each tray including a source receiving portion and an outer circumferential wall having an outer wall surface, the outer circumferential wall including at least one projecting flange thereon, each projecting flange having an outer circumferential flange surface and a second surface extending from the circumferential flange surface in the direction of the outer wall surface, and a clamp, actuable between a circumferentially expanded condition and a circumferentially reduced condition, wherein, in the circumferentially reduced position, contact the second surface of the first tray and the second surface of the second tray.

### CROSS-REFERENCE TO RELATED APPLICATIONS

This application claims benefit of U.S. provisional patent application Ser. No. 63/517,807, filed Aug. 4, 2023, which is herein incorporated by reference.

### BACKGROUND OF THE DISCLOSURE

### Field of the Disclosure

The present disclosure relates to the field of precursor sources for the delivery of a gaseous precursor to an end use location, for example to a semiconductor or other type of processing chamber where the precursor, in gaseous or vaporous form, is used to form a deposition material on a substrate or otherwise react with a substrate or one or more material layers thereon. More particularly, the present disclosure relates to the field of sources of precursors formed by the sublimation or evaporation of a material to form the precursor gas.

### Description of the Related Art

Precursor sources are known in the art and are used to deliver a vapor or gaseous precursor to an end use environment, for example, provide a gas to form, or etch, a thin film coating on a substrate. In the case of semiconductor processing, the sources are used to deliver a gaseous reagent to a processing environment, wherein the reagent, or a component thereof, reacts with another material in the processing environment to form a film layer on a material substrate or remove a material from the substrate, or simply form a deposition material such as a deposition layer on the substrate. Known reagents are used to form deposition layers on semiconductor substrates or on film layers previously formed thereon, or etch or reactively remove a portion of the semiconductor substrate or a material previously formed thereon, or otherwise interact with the surface of the substrate or a material disposed thereon.

One known source of gases used in a processing environment is a sublimation source, wherein a solid precursor is sublimated, in other words converted directly or nearly directly from its solid state to its gaseous state, and the evolved gaseous precursor is flowed to the processing environment, for example to the interior volume of a semiconductor processing chamber. To sublimate the deposition material from the solid to gaseous state, the material is heated to its sublimation temperature at the internal pressure of the sublimation source. Another type of source is a vaporizer, wherein a liquid is heated to evolve a vapor or a gas thereof for delivery to a use location.

One known source uses a plurality of trays configured to hold the solid material to be sublimated or vaporized, and the trays are stacked one over the other with the uppermost tray having a cover thereover Each tray in this system includes a generally flat base portion, and a circumferential body, thicker than the flat base portion, and extending from the flat base portion in the direction away from the flat base portion, such that when the underside of the flat base portion of a next tray is located thereover, the circumferential body of that next tray sits on the circumferential body of the tray below. Thus, a sublimation or vaporization volume is formed between the flat base portion of a first tray and the underside of the flat base portion of a next tray stacked thereover. Each flat base portion includes a plurality of passages extending therethrough, from the underside of the precursor receiving side thereof, to allow gas from a tray or trays therebelow, and a carrier gas, to flow therethrough. A gas outlet is connected to the volume formed between the uppermost tray and the cover. A carrier gas, for example argon or the like which is non-reactive with the gas evolved during sublimation of the solid material or vaporization of the liquid material, is flowed into the volume formed between the lowermost tray and the tray directly thereover to help push or carry the evolved gas toward the sublimation material in the next tray in the stack of trays. The gas evolved from the material in each of the trays is thus flowed therefrom through the trays between that tray and the outlet. The carrier gas assures a positive flow of the evolved gas from the trays toward the gas outlet.

Heating of the precursor to the sublimation temperature is provided by a heater embedded in the circumferential body of each tray. This heats the tray to increase the temperature of the tray to the sublimation temperature of the solid precursor at the pressure in the source, or to the vaporization temperature where a liquid precursor is employed. A plurality of bolt holes extend through each circumferential body, such that a plurality of bolts, or threaded studs, can be extended therethrough and fastened with a fastener at one or both ends thereof to secure the circumferential bodies, and thus the trays, together.

### SUMMARY OF THE DISCLOSURE

In one aspect, a gas source includes a plurality of trays including at least a first tray and a second tray, each tray including a source receiving portion and an outer circumferential wall having an outer wall surface, the outer circumferential wall including at least one projecting flange thereon, each projecting flange having an outer circumferential flange surface and a second surface extending from the circumferential flange surface in the direction of the outer wall surface, and a clamp, actuable between a circumferentially expanded condition and a circumferentially reduced condition, wherein, in the circumferentially reduced position, contact the second surface of the first tray and the second surface of the second tray.

In another aspect, a gas source includes a plurality of trays including at least a first tray and a second tray, each tray including a source receiving portion and an outer circumferential wall having an outer wall surface and a separate heater associated with each of the first tray and the second tray.

In a further aspect, a method of servicing a gas source includes providing plurality of trays including at least a first tray and a second tray, each tray including a source receiving portion and an outer circumferential wall having an outer wall surface, the outer circumferential wall including at least one projecting flange thereon, each projecting flange having an outer circumferential flange surface and a second surface extending from the circumferential flange surface in the direction of the outer wall surface, providing a clamp, actuable between a circumferentially expanded condition and a circumferentially reduced condition, wherein, in the circumferentially reduced position, contact the second surface of the first tray and the second surface of the second tray, monitoring the condition of at least one tray, and removing at least one tray from the plurality of trays by actuating the clamp from the circumferentially reduced condition to the circumferentially expanded condition while maintain any other clamp between adjacent trays in the circumferentially reduced condition.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is an isometric view of the exterior of a source hereof.

FIG. 2 is a sectional view of the source of FIG. 1.

FIG. 2A is a partial sectional isometric view of the source of FIG. 1, having heated clamps clamping together adjacent trays and one of the trays and a base of the source.

FIG. 3 is an isometric view of the precursor receiving side of a tray of the source of FIGS. 1 and 2.

FIG. 4 is an isometric view of the obverse side of the tray of FIG. 3.

FIG. 5 is a partial sectional view showing the clamping paradigm to clamp a tray to a cover of the source of FIGS. 1 and 2.

FIG. 6 is a partial sectional view of the cover and adjacent tray of FIG. 1, showing the connection of the carrier gas tubing into the source.

FIG. 7 is a partial sectional view of the source of FIGS. 1 and 2, showing the opening on the carrier gas flow volumes of a tray into a carrier gas manifold located between a tray and the base.

FIG. 8 is a partial sectional view of the source of FIGS. 1 and 2, showing the connection of the base to an adjacent tray.

FIG. 9 is an isometric view of a clamp used to hold the trays of the source of FIGS. 1 and 2 clamped together.

FIG. 10 is a sectional view of an alternative clamp to that of FIG. 9.

FIG. 11 is an isometric view of the alternative clamp of FIG. 10.

FIG. 12 is a schematic view of the heater control system for the source of FIG. 1.

FIG. 13 is an isometric view of a tray with an alternative embedded heater layout.

FIG. 14 is an isometric view of an additional alternative embedded heater layout.

### DETAILED DESCRIPTION

Herein, a sublimation source, comprising at least one tray on which a source precursor for providing a gaseous reagent or gaseous precursor therefrom, is provided. Here, each tray includes a precursor receiving portion surrounded by a flange providing a support body for the tray, and a heat source located other than within the flange, for example disposed on or in the precursor supporting side of the tray, surrounding the tray flange, or both, and the outer circumferential surface of each tray includes at least one circumferential flange rib extending radially outwardly therefrom. Where multiple trays are employed in a single source, each tray is secured to the next adjacent trays by a circumferential clamp engaging with the circumferential flange rib of two adjacent trays. A cover, including a circumferential cover rib extending about its periphery, is clamped to the last tray in a stack of trays by a circumferential clamp engaging a circumferential rib of the last tray and of the cover. A base, including a circumferential base rib extending about its periphery, is clamped to the first tray in a stack of trays by a circumferential clamp engaging a circumferential rib of the first tray and of the base. A carrier gas supply port is in fluid communication with the first tray in the stack of trays, and a carrier gas outlet is connected to the last tray in the stack of trays. The precursor-receiving portion of each tray includes at least one flow port extending therethrough from the non-precursor receiving surface to the precursor-receiving surface thereof, and the flow port may be configured as a tube extending away from the precursor-receiving surface of the tray. A hollow annular boss may extend from the precursor-receiving surface of each tray, such when the trays are clamped together, an access conduit is formed to extend through the plurality of trays, and a monitoring access is thus provided to each tray. Sensors may be extended through the access conduit to different ones of the trays, to enable real time monitoring of each tray and the precursor material therein. The base and the facing surface of the first tray form a carrier gas manifold therebetween, whereby carrier gas injected through the gas supply port passes thereinto and thence into the at least one flow port of the lowermost tray. Gas evolved from the precursor source on each tray and the carrier gas passes through the at least one flow port of each tray thereover, until the final tray, where it flows outwardly of the source gas outlet.

Here, in contrast to prior precursor sources, the precursor-receiving surface of any one of the trays can be readily accessed by unclamping that tray from the next adjacent tray clamped thereover, without the need to disassemble or release the clamping pressure on all of the trays in the entire source to reach any single tray. Additionally, the conditions in each tray can be actively monitored, to enable individual control of each tray heater to enable tray-by-tray control of the solid or liquid precursor temperature and thus gas evolution therefrom.

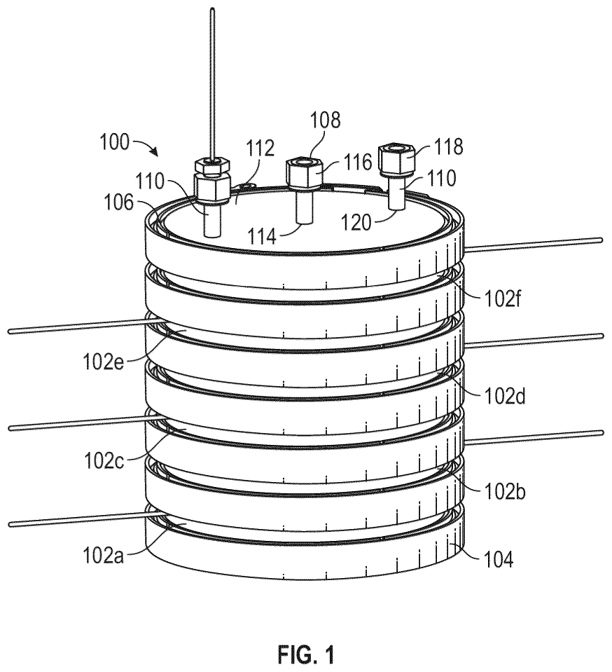

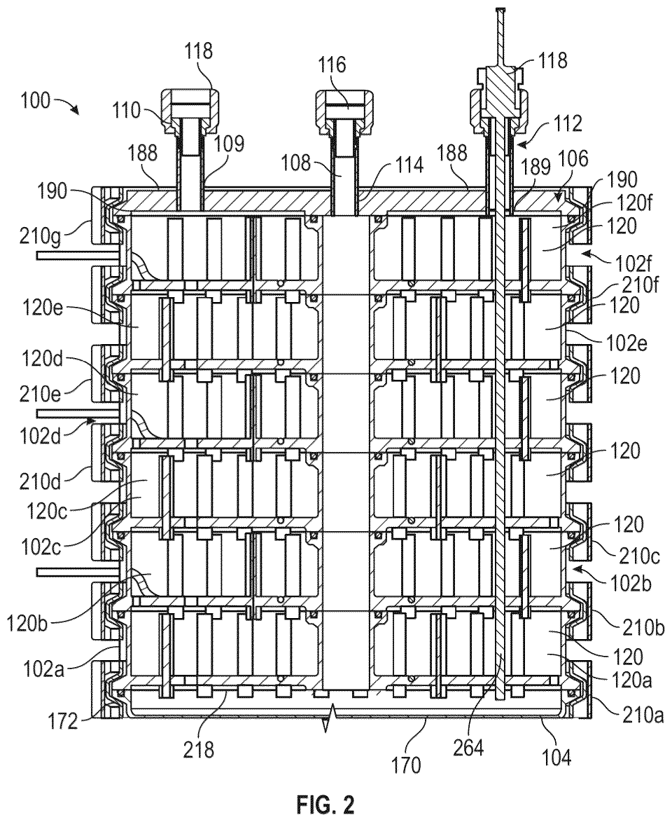

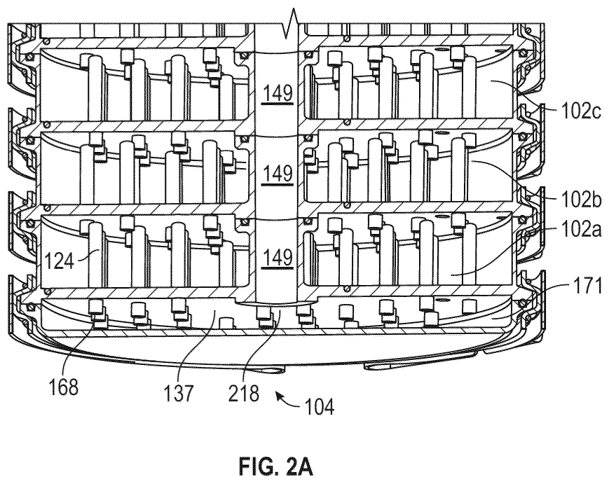

Referring initially to FIGS. 1 and 2, a sublimation source 100 is shown in an isometric and a sectional view, and the source 100 is shown not covered in insulation or received in a protective sheath. Here the source 100 includes a plurality of trays 102 stacked one over the other, (here, by way of example and not limitation, six trays 102a-f) each tray 102 substantially identical to each other tray 102 in the source 100, a base 104 connected to the first tray 102 (here lowermost tray 102a) in the stack of trays 102a-f, and a cover 106 connected to the last tray 102 in the stack, (here the uppermost tray 102f). A carrier gas inlet 108 extends through the cover 106 to enable flowing of a carrier gas into the source 100, and an evolved and carrier gas outlet 110 extends outwardly of the cover to enable gaseous precursor to flow from the source 100. Additionally, a monitoring stem 112 extends outwardly of the cover 106.

Here, the carrier gas inlet 108 is a length of tubing extending inwardly of, and secured to, a carrier gas opening 114 provided therefor in the cover 106, such as by being welded into the carrier gas opening 114 in the cover 106. Carrier gas opening 114 is centered on the circular profile of the cover 106. A carrier inlet gas fitting 116 for connection of the carrier gas inlet 108 to a source of a carrier gas, is connected to the end of the tubing of the carrier gas inlet 108 distal to the cover 106. Here, the gas outlet 110 is a length of tubing extending through the cover 106 and terminating adjacent to the last, here sixth, tray 102f (FIG. 2), such as by being welded to an outlet opening 109 through the cover 106. A carrier outlet gas fitting 118 is connected to the end of the tubing of the gas outlet 110 distal to the cover 106, for connecting the gas outlet 110 to a tubing for eventual flow to the location of use of the gas evolved in the source 100.

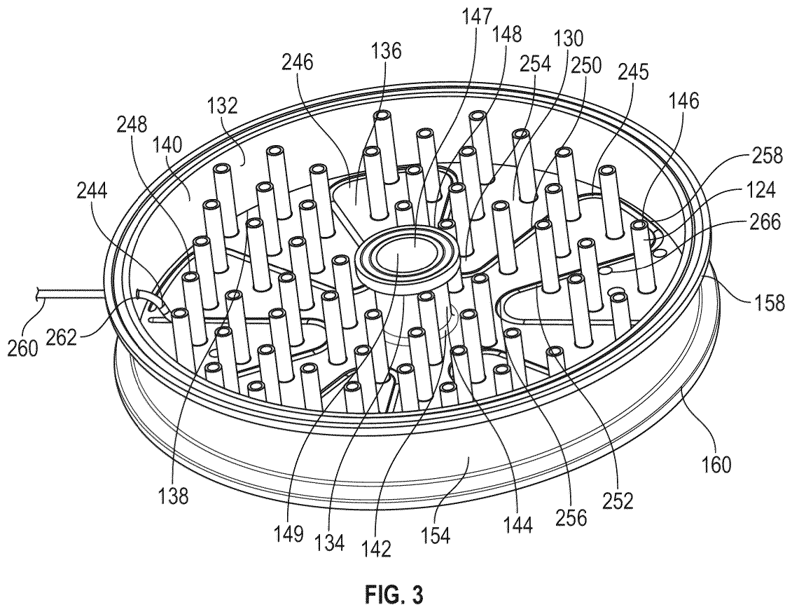

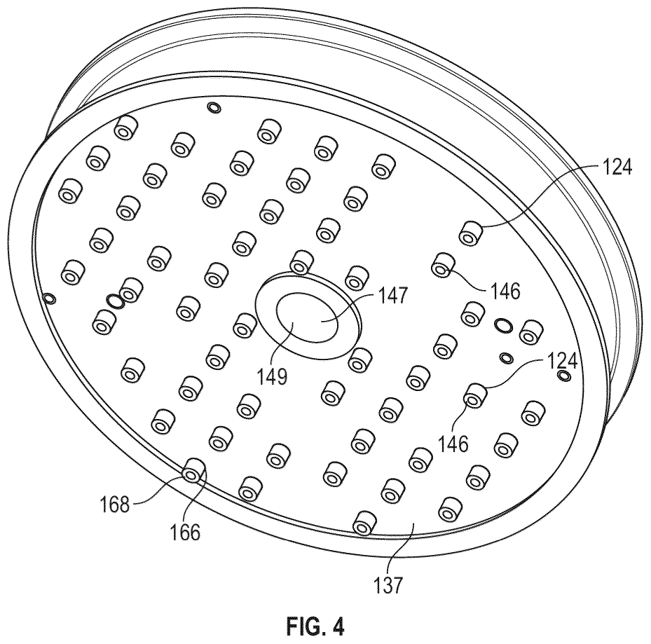

Referring now to FIGS. 3 and 4, each tray 102 is generally circular in plan view, and each includes an annular precursor receiving portion 130 surrounded by an outer annular set-off wall 132 in the form of a thin walled annular pillar. A central annular boss 134 in the form of a thin walled annular pillar is disposed generally centered in the precursor-receiving portion 130. Here, precursor receiving portion 130 includes a generally flat planar precursor receiving surface 136 and an opposed annular surface 137, and is annular in plan view and bounded at its outer circumferential end 138 by the inner wall 140 of the set off wall 132, and at its inner circumferential end 142 bounded by a circumferential central annular boss wall 144 of a central annular boss 134. Here, preferably, the precursor-receiving portion 130, set off wall 132 and the central annular boss 134 of each tray 102 are configured out of a single piece of material or stock, so that no welding or other fastening or connecting of them together is required. The single piece of material or stock may be composed of quartz, stainless steel, or other materials based on the desired operating temperature of the source 100 and the reactivity of the solid and evolved gaseous precursor to different potential tray materials.

A plurality of evolved gas flow passages 146 are provided in the form of tubes 124 extending through the precursor-receiving portion 130 and providing the evolved gas flow passages 146. Here, each of the evolved gas flow passages 146 extends outwardly and generally perpendicular to the precursor receiving surface 136 and also from the opposed annular surface 137 (FIG. 4) which faces an adjoining tray 102 or the base 104 in the case of tray 102a (FIG. 2). The tubes 124 forming the evolved gas flow passages 146 may be formed (machined) out of the same block or billet of material as the precursor receiving portion 130, outer annular set-off wall 132 and central annular boss 134. Alternatively, the precursor receiving portion can have a plurality of tube receiving openings formed therethrough, such as by drilling thereof, and the tubes 124 welded or otherwise secured into these openings. The evolved gas flow passages 146 of the tubes 124 formed or affixed to each tray enable gas evolved in a next tray 102 upstream in a carrier gas flow direction to flow into the tray, as well as allowing the carrier gas to flow into the first tray 102a from the space between the opposed annular surface 137 of the first tray 102a and the base 104. Thus, the gas flow passages 146 enable gas flow from a space between the tray 102a and the base 104, sequentially into an evolved gas volume 120 of each tray 102a-f respectively, and thence to the gas outlet 110. Here, inner gas flow wall 146 extends outwardly beyond the opposed annular surface 137. Thus, a circumferential stub 166 of the tube 124 extends outwardly of the opposed annular surface 137, within which the inner gas flow passage 146 extends, and terminates in a flat planar annular boss wall 168.

Central annular boss 134 includes the central annular boss wall 144 forming a portion of the outer circumferential surface of the central annual boss 134, and an inner carrier gas flow passage wall 147 bounding a carrier gas inlet passage 149 extending through the precursor receiving portion 130 of each tray 102 and generally centered therethrough. The end of the central annular boss 134 distal to the precursor receiving surface 136 includes an enlarged annular ring shaped portion 148 having a flat, planar inner next tray facing surface 150 having a circumferential seal ring groove 152 extending inwardly thereof (FIG. 6).

Set off wall 132 surrounds the evolved gas volume 120 and it includes the inner wall 140 and an outer circumferential wall 154. Outer circumferential wall 154 includes a generally right circumferential portion 156 bounded at opposed ends by a first and a second projecting portion 158, 160, respectively forming a flange extending radially outwardly of the outer circumferential wall 154.

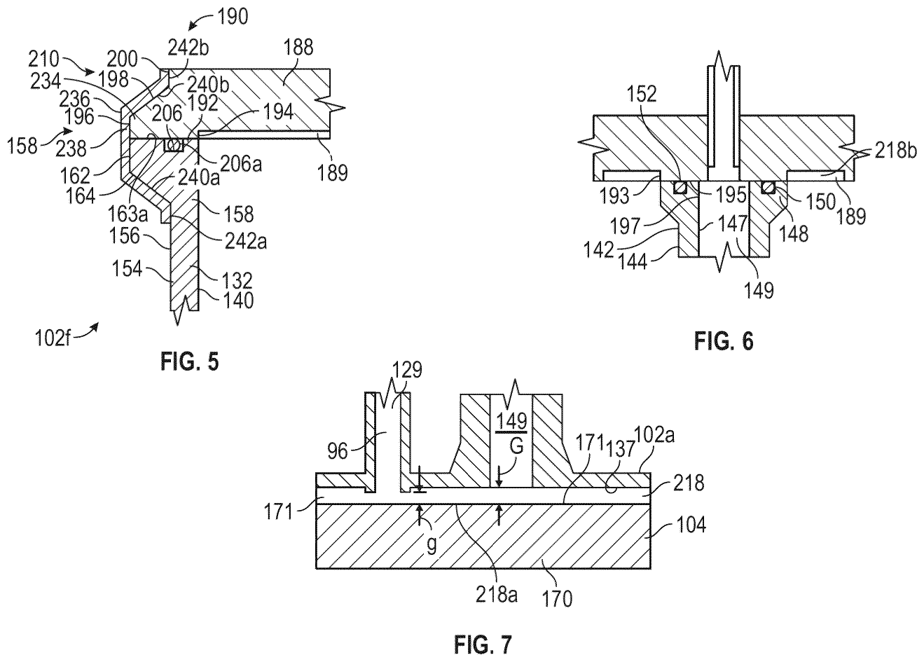

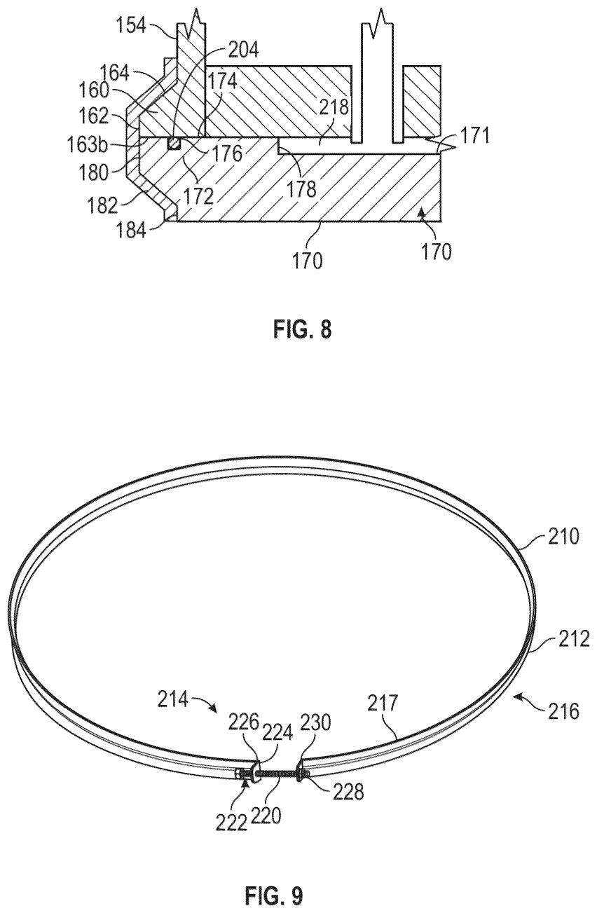

As illustrated in FIGS. 5 and 8, each of the first and second projecting portions 158, 160 of the tray 102 include an outer right circumferential portion 162, a frustoconical tapered wall 164 extending from the outer right circumferential portion 162 to the outer circumferential wall 154 of the tray 102, and a flat outer next tray facing surface 163 extending orthogonally and inwardly of the outer right circumferential portion 156. Here, the flat outer next tray facing surfaces 163 on each tray include a first flat outer next tray facing surface 163a (FIG. 5) and an opposed second flat outer next tray facing surface 163b (FIG. 8). First flat outer next tray facing surface 163a includes a seal ring groove 206a extending circumferentially therein.

Referring to FIGS. 2, 7 and 8, base 104 is a generally circular, in plan view, element, having a base wall 170 generally having a circular, in plan view, inwardly facing base wall surface 171 and a perimeter lower flange 172. Lower flange 172 includes a generally flat, planar, tray contacting surface 174 including a base seal groove 176 extending inwardly thereof and circumferentially around the base wall 170, the tray contacting surface 174 spaced from the base wall surface 171 by base stand off wall 178 which extends from the outer perimeter of the base wall surface 171 to the tray contacting surface 174. The outer circumferential surface of the base 104 includes a generally right circular outer circumferential base wall 180 extending in the base wall 170 direction from the tray contacting surface 174, an inwardly tapering frustoconical base tapered wall 182 extending therefrom, and an inner circumferential base wall 184 extending generally parallel to the outer circumferential base wall 180 to terminate at the base wall outer 186.

Referring to FIGS. 2, 5 and 6, the cover 106 has a similar configuration to that of the base 104, except it also includes the openings therethrough for receipt of the carrier gas inlet 108, carrier gas outlet 110 and monitoring stem 112. Thus, cover 106 is a generally circular, in plan view, element, having a cover wall 188 having a generally circular, in plan view, plenum wall surface 189 facing the precursor receiving surface 136 of the facing tray 102, here 102f, and a perimeter upper flange 190. Upper flange 190 includes a generally flat, planar, last tray contacting surface 192 extending circumferentially around the tray facing side of the cover wall 188, the upper tray contacting surface 192 spaced from the cover wall 188 by cover stand off wall 194 which extends from the outer perimeter of the cover wall 188 to the upper tray contacting surface 192. An inner stand off wall 193 (FIG. 6) is generally located at the circumferential center of the plenum wall surface 189 and extends circumferentially from the plenum wall surface 189 and terminates at a generally flat, annular inlet sealing wall 195. The outer circumferential surface of the cover 106 includes a generally right circular outer circumferential cover wall 196 extending away from the upper tray contacting surface 192, and an inwardly tapered frustoconical cover wall 198 extending therefrom, and an inner circumferential cover wall 200 extending from inwardly tapered frustoconical cover wall 198 in the direction away from the upper tray contacting surface 192.

To assemble a source 100, a precursor source material is loaded onto the precursor receiving surface 130, such that the precursor source material does not extend above the ends of the tubes 124 distal from the precursor receiving surface 136. The plurality of trays 102 are connected, and secured together, such that the flat planar annular boss wall 168 of a tray 102 faces and is in contact with the flat, planar inner next tray facing surface 150 of the adjacent tray 102, with a seal ring such as an O-ring located in the circumferential seal ring groove 152. Likewise, the first flat outer next tray-facing surface 162a of a tray faces and contact the opposed second flat outer next tray facing surface 162b of the adjacent tray 102, and a seal ring such as an O-ring is disposed in the seal ring groove 206a. This arrangement creates an outer circumferential seal and an inner circumferential seal around the precursor-receiving surface 136 and evolved gas volume 120 of one tray and the facing opposed annular surface 137 of the next tray 102.

Cover 106 and base 104 are connected to the stacked trays 102a-f at the opposed ends of the stack of the trays 102a-f, here the cover 106 is connected to the tray 102f, and the base 104 is connected to the tray 102a. A seal ring 204 is provided in the base seal groove 176 to effect a seal between the base 104 and the tray 102a, when the tray-contacting surface 174 is biased against the next tray facing surface 162a of tray 102a. Likewise, a seal ring 206 is disposed in the seal ring groove 206a and provides a seal between the tray 102e and the cover 106, when the upper tray-contacting surface 192 is biased against the next tray facing surface 162b of tray 102f. A seal ring

By connecting together a plurality of trays 102, for example trays 102a-f, an evolved gas volume 120 is formed between the opposed annular surface 137 of one tray 102, for example of tray 102b, and the precursor receiving surface 136 of the adjacent tray 102, for example of tray 102a, facing the opposed annular surface 137 of tray 102b. Within this evolved gas volume 120 the precursor material, in solid or liquid form, is located on the precursor receiving surface 136, and heated to evolve a gaseous or vaporous precursor therefrom. Additionally, with respect to the plurality of evolved gas volumes 120 (one for each tray 102), one or more tubes 124 extend from each of evolved gas volumes 120 to the next adjacent evolved gas volume 120 over the precursor receiving surface 136 of the next adjacent tray 102 in the direction from the base 104 to the cover 106, i.e., in the direction of gas flow through the source 100. Specifically, the evolved gas flow passages 146 of the tubes 124 extending through the precursor receiving portion 130 of the tray 102b allow gas, including the precursor gas evolved in the evolved gas volume 120a between the solid precursor receiving surface 136 of tray 102a and the opposed annular surface of tray 102b, and the carrier gas flowed into evolved gas volume 120a, to flow into evolved gas volume 120b. Likewise, the evolved gas flow passages 146 of the tubes 124 extending through the base of the tray 102c allow gas, including the precursor gas evolved in evolved gas volume 120b and the carrier gas to flow into evolved gas volume 120c, and the evolved gas flow passages 146 of the tubes 124 extending through the base of the tray 102d allow gas, including the precursor gas evolved in evolved gas volume 128c and a carrier gas to flow into evolved gas volume 120d. The evolved gas flow passages 146 of the tubes 124 extending through the base of the tray 102e allow gas, including the precursor gas evolved in evolved gas volume 120d and a carrier gas to flow into evolved gas volume 120e. The evolved gas flow passages 146 of the tubes 124 extending through the base of the tray 102f allow gas, including the precursor gas evolved in evolved gas volume 120e and a carrier gas to flow into evolved gas volume 120f. Here, evolved gas volume 120f is formed between the precursor receiving surface 136 of tray 102f and the inner facing plenum wall surface 189 of the cover 106. From the evolved gas volume 120f the precursor gas evolved in all of the evolved gas volumes 120a-f, and the associated carrier gas, is flowed into a precursor exhaust plenum 218b formed between the plenum wall surface 189 of the cover 106 and the facing surfaces of the last tray 102, here tray 102f. Thence, the gas flows outwardly of the gas outlet 110. To introduce the carrier gas into each evolved gas volume 120a-f, a carrier gas source is connected to the carrier gas inlet 108 to flow a carrier gas thereinto. This carrier gas thence flows through the carrier gas inlet passages 149 in each of the trays 102f-a to a carrier gas plenum 218a formed between the inwardly facing base wall surface 171 of the base 104 and the opposed annular surface 137 of a facing tray 102, here tray 102a as best shown in FIG. 2A. The flat planar annular boss wall 168 of the stub 166 of each of the tubes 124 extends outwardly of the opposed annular surface 137 and is spaced from the base inwardly facing wall surface 171 by a distance g which is greater than zero length, and less than the distance G between the annular opposed wall 137 and the base wall surface 171 (FIG. 7). The carrier gas thus enters the evolved gas volume 120a, where it mixes with gas evolved from the solid precursor on the precursor receiving surface 136 of tray 102a. The mixture of the carrier gas and the evolved gas thence flows through appropriate ones of the evolved gas flow passages 146 of the tubes 124 in trays 102b to 102f, and thus sequentially through the evolved gas volumes 120b to f, to the gas outlet 110 of the source 100 and thence to a desired use location. The flow of the carrier gas helps ensure a positive gas flow in the direction of the carrier gas plenum 218a to the gas outlet 110 to ensure the evolved precursor flows out of the source 100 through the gas outlet 110. The carrier gas is prevented from leaking from the carrier gas inlet passages 149 into the adjacent circumferentially surrounding evolved gas volumes 120 by a seal ring in the circumferential seal ring groove 152 of the central annular boss 134. The seal ring spans the gap between the base seal ring groove 152 and the facing surface of the inlet sealing wall 195 (FIG. 6).

Although the precursor material from which the precursor gas is formed is described herein as a solid, the source 100 can also be used for liquid precursors. For liquid precursors, the liquid precursor can be poured over the precursor receiving surface 130 of each tray such that it does not overflow into the ends of the evolved gas flow passages 146 of the tubes 124 located distal to the precursor receiving surface 130 of the associated tray 102.

Here, releasable clamps 210 are used to hold the base 104 to tray 102a, tray 102a to tray 102b, tray 102b to tray 102c, tray 102c to tray 102d, tray 102d to tray 102e, and cover 106 to tray 102e. Referring to FIGS. 5, 8 and 9, each of the clamps 210 used is substantially identical within manufacturing tolerance, and includes a hoop portion 212 and a clasp portion 214. Here, clamp 210a secures the base 104 to the tray 102a, clamp 102b secures tray 102a to tray 102b. Clamp 210c secures tray 102b to tray 102c. Clamp 210d secures tray 102c to tray 102d, and clamp 102e secures tray 102d to tray 102e. Clamp 210 f secures tray 102e to tray 102f, and clamp 210g secures tray 102f to the cover 106. As described herein, each of the trays 102a-f and the cover 106 and base 104 include an outer peripheral portion configured to mate with the clamp 210. Here, the connection of the clamp 210 to secure the cover 106 to the tray 102f will be described, but the clamping of the base 104 to tray 102a, and each tray 102 to the next adjacent tray 102, is identical within manufacturing tolerance.

Here, the clamp 210 is configured to be reusable, and includes a hoop portion 212 and a clasp portion 214. Hoop portion 212 includes a includes a cut ring shaped portion 216 having a single continuous configured strap 217 connected, at circumferentially opposed ends thereof, to the clasp portion 214. Clasp portion 214 here is configured as a threaded fastener 220 extending through a ferrule 222, a through opening 224 extending through an outwardly projecting first end 226 of the hoop portion 212 and into and threading engaged with a threaded opening 228 in a second enlarged portion 230 at the second circumferential end of the hoop portion 212. Here the ferrule 222 is configured as a hollow tubular member having an inner diameter sized to allow the fastener 220 to freely slide therethrough, and an outer diameter larger than the diameter of the through opening 224. When the fastener 220 is backed out of or retracted but still in the threaded opening 228, the inner circumference of the hoop portion 212 is sufficiently greater than the outer circumference of the circumferential cover wall 196 of the cover 106 (FIG. 5), and thus the hoop portion 210 can be placed circumferentially thereabout. As the fastener is threaded inwardly of the threaded opening 228, the strap 217 of the clamp 210 is reduced in diameter, to come into contact with the outer surfaces of portions of a pair of adjacent trays 102, tray 102f and the cover 106, and tray 102a and the base 104.

As shown in FIG. 5, clamp 210 is configured with a contoured inner surface 234 having a profile in section that is matching or nearly matching the outer surface profile of the outer circumferential mating portions of the cover 116 and tray 102f (or two trays 102, or tray 102a and base 104. Thus, clamp 210 includes a generally circumferential first upright wall 236 having a generally circumferential flat inner wall surface 238, a first and a second clamp tapered portions 240a, b extending radially inwardly of the upright wall the same distance from opposed sides thereof, and first and second inner circumferential walls 242a, b, extending generally parallel to the first upright wall 236 and having the same length extending from the inward ends of the first and second tapered walls 240a,b. By positioning the clamp 210 about the outer circumferential cover wall 196 of the cover 106 and the adjacent outer right circumferential portion 162 of the tray 102f adjacent to the cover 106, and turning the threaded fastener 220 such that the threaded fastener 220 rotates inwardly of the threaded opening 228, the strap 217 of the clamp 210 will move radially inwardly of itself to position the first and the second clamp tapered portions 240a, b to contact the inwardly tapered frustoconical cover wall 198 of the cover and the adjacent frustoconical tapered wall 164 of the tray 102f. A seal ring, for example an O-ring or other compressible ring is provided in the groove 206a and contacts an inner surface thereof, and is sized to extend, in its uncompressed state, outwardly of the groove 206a. Thus, when the cover 106 is placed on the tray 102f, the upper tray-contacting surface 192 thereof may be spaced from the next tray facing surface 163a by the seal ring 206. As the clamp 210 is farther radially compressed by further turning the threaded fastener 220 such that the threaded fastener 220 moves further inwardly through the threaded opening 228, the movement of the first and a second clamp tapered portions 240a, b radially inwardly will cause inwardly tapered frustoconical cover wall 198 of the cover and the adjacent frustoconical tapered wall 164 of the tray 102f to move toward one another. This compresses the seal 206 in the seal groove 206a to eventually bring the next tray facing surface 163a into contact with the upper tray-contacting surface 192 to secure the cover 106 to the tray 102f. In the same manner the adjacent second projecting portion 160 of tray 102f is secured to the first projecting portion of tray 102e with a clamp 210, and each second connecting portion of the remaining trays 102 is secured to the first connecting portion of the adjacent tray 102 using a clamp 210, and the second connecting portion of tray 102a is secured to the perimeter lower flange 172 of the base 102 using a clamp 210. In this manner a complete source 100 is assembled, in which the precursor receiving portions 130 of the trays are in fluid communication with one another, and with a carrier gas inlet 108 and an evolved gas outlet 110 but otherwise sealed off from the surrounding ambient around the source 100.

In one aspect hereof, a heating element is integrally provided for each tray 102 and is embedded inwardly of the precursor receiving surface 136 of the tray 102. As shown schematically in FIG. 3, a heating element 244 extends in a circumferential truncated sinusoidal fashion in a circumferential truncated sinusoidal heater groove 246 extending inwardly of the precursor receiving surface 1 of the tray 102. Here, the heater groove 246 includes five full lobes 245 and one partial lobe 248, wherein each full lobe 245 includes a first radial extending portion 250, a second radially extending portion 252, a first inner curved portion 254 extending from the radial inner end of the first radially extending portion 250, a second inner curved portion 256 extending from the radial inner end of the second radial portion 252, and an outer curved portion 258 extending between the outer radial ends of the first and second radial extending portions 250, 252. The outer curved portion generally extends along an arc centered on the center of the gas inlet passage 149. The first curved portion 252 of each lobe 240 connects directly to the second curved portion of the next lobe 240, such that a continuous heater groove 246 is formed in the precursor receiving portion 130. At opposed ends of the heater groove 245 forming the partial lobe 248 the radial outer end of the first radial extending portion 250 ends and is spaced from the adjacent outer curved portion 258 at the other end of the heater groove 245.

The heating element 244 is here configured as a resistance heating element composed of an inner resistance wire element and an outer jacket of a metal that is inert with respect to the precursor(s) to be processed in the source 100. As is known in the art, this heating element 244 includes the resistance wire element and wiring (not shown) encased in a flexible tubular jacket 260. The tubular jacket 260 extends outwardly of the outer wall of the tray through a heater opening 262 provided for that purpose, and is press fit, staked, welded or vacuum brazed into the heater groove 246 over the full length, or nearly the full length, of the heater groove 246. Where welded, the welding material can cover the tubular jacket 260 so it is not exposed to the interior gas evolving volume of the tray 102, or all or a portion of the tubular jacket 260 can remain exposed to the gas evolving volume. The heater tubular jacket 260 extends through an opening 262 provided therefor through the set-off wall 312 and is secured therein using a leak tight method (between the inner wall of the opening and outer surface of the jacket 260), which includes but is not limited to, being welded, swaged, brazed, etc. to the interior or exterior surface of the heater opening 262 or surrounding surface to seal the interface between the heater tubular jacket 260 and the opening 262. The heating element 244 is connected to a power supply (not shown) to the exterior of the tray 102 and source 100 to provide electrical power to the resistance wire element of the heating element 244 to raise the temperature thereof, and of the precursor receiving surface 136 of the tray 102, to the or above the sublimation temperature of a material to be sublimated to form the precursor gas. Although the heater groove 246 is shown as having six lobes, other heater layouts can be used. The intent of the heater groove 246 layout is to form or create an acceptably uniform temperature across the sublimation source receiving surface 136 with reasonable manufacturing cost for the source. The heater 244 is selected to provide the desired temperature within the precursor-receiving surface 130 of the tray that is sufficiently high to cause a solid precursor placed thereon to sublimate and evolve a gas therefrom, or to heat a liquid precursor to cause vaporization or evaporation thereof. Temperatures on the order of greater than 20 degrees C., and to or over 1200 degrees C., are contemplated.

In use, the source is initially loaded with a solid precursor at the local ambient temperature such as room temperature (20 C), or a different temperature that is still below the sublimation temperature of the precursor at the local ambient pressure to which the solid precursor is exposed during loading of the precursor into the trays 102 (or a very low vaporization temperature of the liquid precursor).

Before loading the solid or liquid procurer into the tray 102a to which the base 104 is attached, the base 104 may be connected to that tray 102a. Then the said or liquid precursor is placed onto the precursor receiving surface 136 of tray 102a. Each subsequent tray 102b-f can then be placed on the just filled tray, filled with precursor, and the next tray 102 placed thereover until the desired number of trays are located on over the other. Then, each tray 102 is clamped to the next adjacent tray 102, if not already attached, the base 106 is attached to the first tray 102a of the stack of trays 102, and the cover 106 is located over and clamped to the last tray 102f of the stack of trays 102. The precursor can be poured or loaded onto the precursor receiving surface 136 of each tray 102 before the stacking of the trays 102 and attachment of the base 104 and cover 106, the precursor can be poured or loaded onto the precursor receiving surface 136 of each tray 102 after the tray 102 is connected to the base 104 or another tray thereover while the precursor receiving surface 136 is openly exposed, or a combination of both methods. The trays 102, base 104 and cover 106 are appropriately connected together by the clamps 210. The heating elements 244 of the source 100 are connected to a power supply, and the source 100 is then ready for use. Here, after being assembled together with the clamps 210, the source can be surrounded in insulation which can be strapped or adhered thereto, placed into a containment vessel, or both.

If there is an issue detected with respect to any tray 102, that tray 102 can be removed and replaced with a new tray 102 without disassembling the entire connected stack of trays. Here, the defective tray 102 is removed by opening the two clamps 210 connecting it to the source, a new tray 102 with precursor therein is placed in the stack where the defective tray 102 was removed, and the clamps 210 are reconnected and tightened to secure the replacement tray 102 into the source 100.

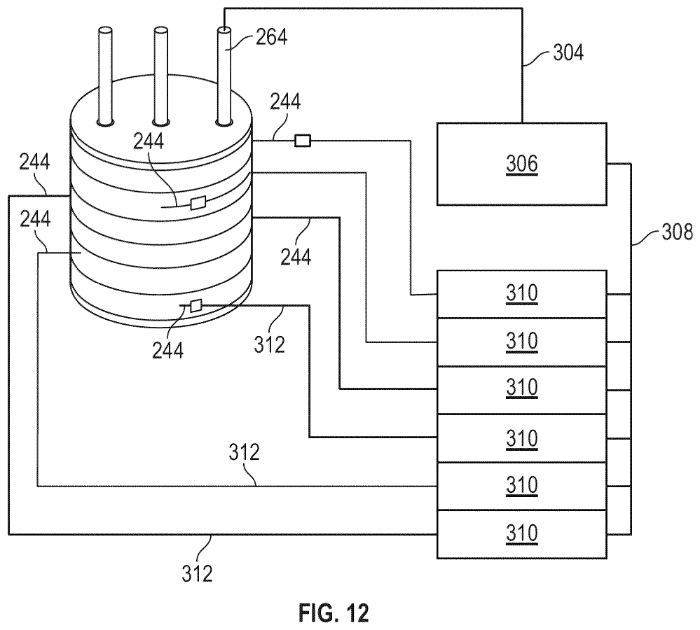

In one aspect hereof, the conditions in the evolved gas volume 120 of each tray 102 as well as the tray 102 temperatures are monitored using a sensor tube 264 (FIG. 2) extending inwardly and through the monitoring stem 112 and through a sensor rod aperture 266 (FIG. 3) extending through the precursor receiving portion 260 of each of the trays 102. The sensor rod may, if desired, be sealed with the sensor rod aperture 266, for example, where a liquid precursor material is used to evolve a gaseous precursor therefrom. For example, the sensor tube 264 can include a plurality of sensors, for example a Fiber Bragg sensing device or (FBG) or another temperature sensor such as a temperature-sensing device such as thermocouples, Resistance Temperature Detector's or infrared sensors. Fiber Bragg technology allows for monitoring and control of up to 16 channels in real-time in conjunction with the thermally controlled integrated tray heaters. Temperature sensing of each of the trays 102, for example by a first temperature sensor located such that the precursor receiving portion 130 of the tray 102 surrounds the location of the sensor in the sensor tube 264, allows for control of the heating element 244 of that tray 102 to increase or decrease the temperature by changing the electrical energy per unit time supplied to that heating element 244, as well as control of the heating element 244 in the precursor receiving portion 130 of the tray overlying the specific tray. For example, using the heater as shown in FIG. 3, the temperature in the evolved gas volume 120 of a given tray, for example tray 102b, is primarily a function of the temperature of the precursor receiving portion of that tray 102b, and secondarily a function of the temperature of the precursor receiving portion of the tray 102c thereover. The temperature of the precursor receiving portion of the tray 102a also has some impact on the temperature of the evolved gas volume 120b of tray 102b. By monitoring the temperature of each precursor-receiving portion of each tray 102, changes in the heating of that tray 102, and trays 102 there adjacent, can be made to control the uniformity of the temperature of the precursor receiving portions of each tray. Also, if desired, a designed variation or gradient in temperature from tray 102 to tray 102 can also be achieved by monitoring the temperatures of each precursor-receiving portion 130 of the trays 102, and controlling the power to each of the heaters to result in a desired temperature variation or gradient. Alternatively, temperature sensing of each of the evolved gas volumes 120, for example by a first temperature sensor located such that the evolved gas volume 120 above a particular tray 102 surrounds the location of the sensor in the sensor tube 264, allows for control of the heating elements 244 on one or both sides of the evolved gas volume 120 to increase or decrease the temperature in the evolved gas volume 120 by changing the electrical energy per unit time supplied to one or both of the heating elements 244 on opposed sides of the evolved gas volume 120. The signal output by the sensors is, in one aspect as shown in FIG. 12, fed via appropriate cabling 304 to a programmable logic controller 306, that can be programmed to output an energy control signal to the heating element power supply(s) 310 through appropriate output cabling 308 to individually control the energy per unit time (power) supplied to each of the heating elements 244 through appropriate power cabling 312 to thereby enable a desired uniformity of the temperatures of the trays 102, resulting in a more uniform conversion of the procurer to a gas or vapor across the plurality of trays 102. As a result, the overall flow rate or precursor per unit time can be maintained over a longer time period, as precursor to be evolved will be in all of the trays 102 at a nearly equal amount over the delivery life of one loading of precursor into the source 100.

For example, by individually controlling the heating elements based on the temperature of the tray 102, the adjacent evolved source volume 120, or both, the trays 102a, f at opposed ends of the stack of trays 102 can receive greater heat energy, and the trays 102c, d near the center of the stack of trays 102 can receive less heat energy, to result in a uniform temperature, within an acceptable temperature range, as among the different trays 102.

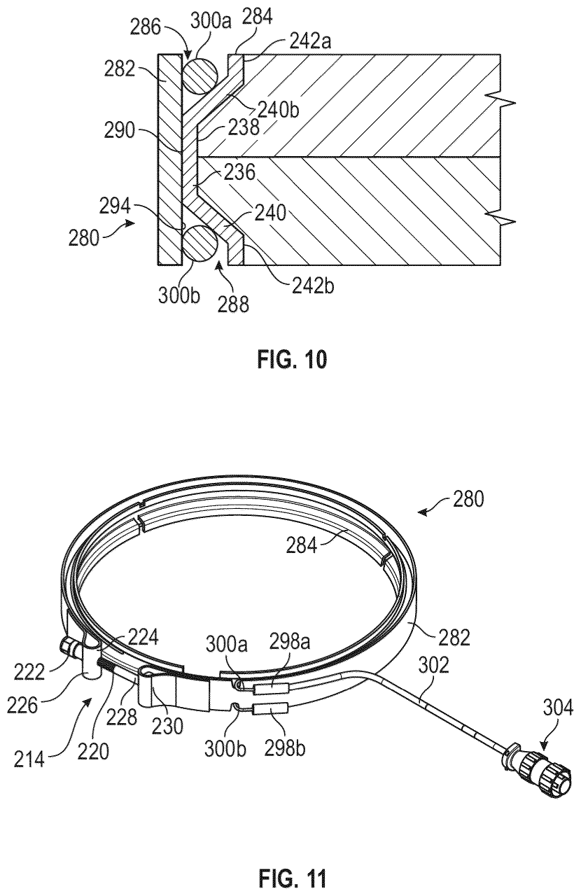

FIG. 11 is an isometric view of an alternative clamp to the clamp 210, and FIG. 10 is a sectional view of this alternative clamp structure. Here, a heated clamp 280 is used in replacement of clamp 210. Heated clamp has the same general construct of clamp 210, including the threaded rod and threaded opening configuration for opening and closing the clamp. In contrast to clamp 210 however, heated clamp 280 is configured of an outer hoop 282 and an inner configured portion 284 having the profile of the clamp 210, such that a first heater receiving recess 286 and a second heater receiving recess 288 are formed between different portions of the hoop 282 and configured portion 284. Here, hoop 282 includes the closure system of clamp 210, modified to be connected to opposed ends of the hoop 282. This includes the clasp portion 214 having the threaded fastener 220 extending through a ferrule 222, a through opening 224 extending through an outwardly projecting first end 226 of the hoop portion 212 and into and threading engaged with a threaded opening 228 in a second enlarged portion 230 at the second circumferential end 232 of the hoop portion 212. When the fastener 220 is backed out of or retracted, but still in the threaded opening 228, the inner circumference of the hoop 282 is sufficiently greater that the outer circumference of the circumferential cover wall 196, and thus the hoop portion 210 can be placed circumferentially thereabout. In the same manner as with clamp 210, rotating the threaded fastener 220 to move inwardly of the threaded opening 228, causes a reduction in the circumference of the hoop 282, and thus of the inner configured portion 284 to bring it into contact with the outer circumferential clamping surfaces of adjacent trays 102, tray 102a and base 104, and tray 102f and cover 106.

Referring to FIG. 10, the inner configured portion 284 of the heated clamp 280 has the same structure as the clamp 210, including the generally circumferential first upright wall 236 having a generally circumferential flat inner wall surface 238, the first and the second clamp tapered portions 240a, b extending radially inwardly of the upright wall the same distance from opposed sides thereof, and the first and second inner circumferential walls 242a, b, extending generally parallel to the first upright wall 236 and having the same length extending from the inward ends of the first and second tapered walls 240a,b. Here, the inner configured portion 284 is segmented into a plurality of partially circumferentially extending sections 292, and the outer circumferential wall surface 290 of the each of the segments 292 is affixed to the inner wall of 294 of the outer hoop 282. First heater recess 286 is formed in a partially circumferentially extending space between the inner wall 294 of the outer hoop 282, and the adjacent outer surfaces of the first tapered portion 240a and first inner wall 242a of the contoured portion 284. Second heater recess 288 is formed in a partially circumferentially extending space between the inner wall 294 of the outer hoop 282, and the adjacent outer surfaces of the second tapered portion 240b and second inner wall 242b of the contoured portion 284.

A first resistance wire heater 300a such as the heating element 244 configured as a resistance heating element composed of an inner heating element and an outer jacket extends circumferentially within the first heater recess 286, and a second resistance wire heater 300b such as the heating element 244 configured as a resistance heating element composed of an inner heating element and an outer jacket extends circumferentially within the first heater recess 288. The tubular jacket extends outwardly of each of the first heater recess 286 and the second heater recess 288 through respective openings through the outer hoop 282, and terminates in a connector 298 (298a, 298b) located outwardly of the outer hoop 282. In FIG. 11, a heater electrical lead 302 and connector 304 for connection to a power supply are shown connected to one of the connectors 298, specifically connector 298a.

The heated clamp 280 is openable over the respective clamping features of the trays 102, cover 106, and base 104 in the same manner as clamp 210. In the heated clamp 280, the segments of the inner configured portion 284 enable the heater tube to compress or expand radially into the space between the adjacent segments as the clamp is tightened and loosened. The heater or heaters in the heated clamps 280 are also independently controllable using the programmable logic controller 306 of FIG. 12 in the same manner as described for controlling the heating from the heating elements 244. The heaters 300a and 300b may be separate heaters and separately powered, or a single heater extending nearly circumferentially about the clamp in one of the first and second heater receiving recesses 286, 288, then into the other of the first and second heater receiving recesses to extend circumferentially around the heated clamp 280 therein.

Each heated clamp 280 spans and contacts either two adjacent trays 102, a tray and the cover 106 or a tray 102 and the base 104. One of the resistance wire heaters 300 in each heated clamp 280 spanning two trays 102 will generally surround the sublimation source receiving surface 132 of one of the trays 102, and the other of the heaters 300 will surround the evolved gas volume 120 of the next tray 102 to which the heated clamp 280 is also connected. The heated clamp 280 can be used in addition to the heating element 244 embedded in the source receiving surface 130, or as a replacement or alternative thereto. Use of both the heater 244 and the surrounding resistance wire heater(s) 300 in the heated clamp 280 can be beneficial to tune the temperature across the surface of the sublimation source receiving surface 132, by limiting the heat loss therefrom at the outer circumferential portion thereof. Additionally, only one of the recesses 286, 288 may receive the heater therein.

Additionally, the heated clamp 280 can be used to clamp two trays 102 together, but not include the resistance wire heaters 300 of other heaters therein.

In use, the source 100 may be surrounded by an insulation jacket, for example a jacket configured of two semi-cylindrical sections and placed together over the source 100 and strapped or adhered together. Additionally, the source (and insulation) can be disposed in another container, a sleeve, or the like.

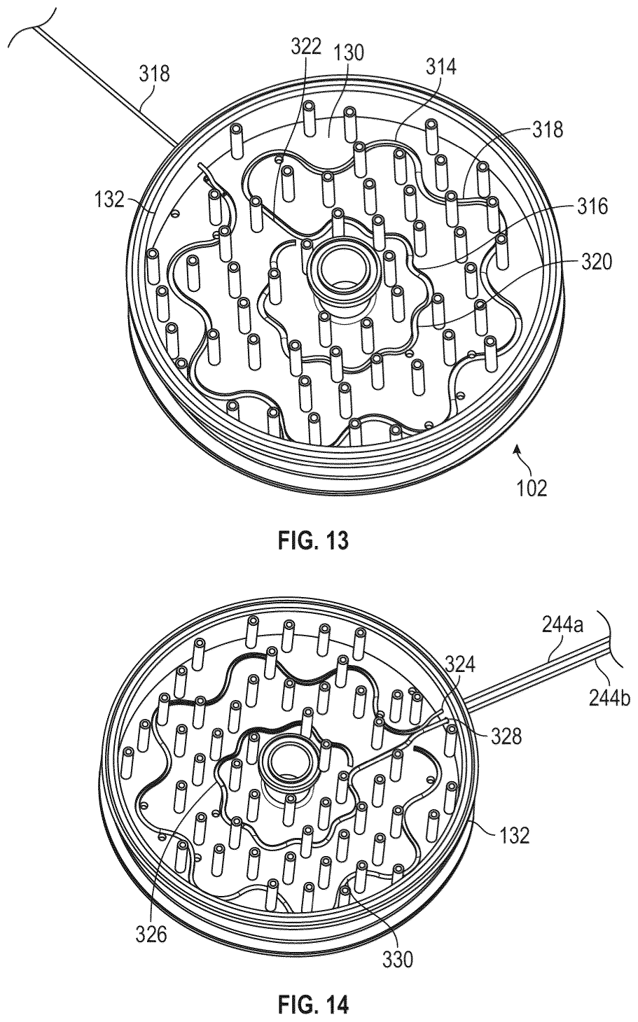

FIGS. 13 and 14 are isometric views of a tray showing alternative heater layouts using the heating element 244 described with respect to FIG. 3. In FIG. 13, the heating element extends through the set off wall 132 as described with respect to FIG. 3, but here extends along an outer circumferential loop 314 on an outer circumferential sinusoidal path groove 318 in the precursor receiving portion 130 of the tray 102 and along an inner circumferential loop 316 on an inner sinusoidal path groove 320 in the precursor receiving portion 130 of the tray 102. A connecting jumper portion 322 of the heating element 244 extends between the inner circumferential loop and outer circumferential loop 316 to connect these loops of the heating element 244 in series. A connecting portion of the heating element 244 extends through the set off wall 132 in a sealed manner. The inner and outer circumferential loops 314, 316 enable spreading of the heat more readily into the precursor receiving portion 103 of the tray 102

In FIG. 14, a dual heater paradigm for the heating of a tray 102 is shown. Here, a first heating element 244a extends from a connection to a power cable (not shown), through a first opening 324 in set off wall 132 and into a first circumferential sinusoidal path groove 326 in the precursor receiving portion centered at a first diameter from the center of the precursor receiving surface 130 of the tray 102. A second heating element 244b extends from a connection to a power cable (not shown), through a second opening 328 and into a second circumferential sinusoidal path groove 330 centered at a second diameter, greater than the first diameter, from the center of the precursor receiving portion. Here, the heating elements 244a, 244 can be separately controlled, separately powered, or both, to achieve a more uniform temperature in the precursor receiving portion in the radial direction thereon. In FIGS. 13 and 14, heater 244 and heaters 244a, b are affixed into the corresponding grooves therefor in the precursor receiving portion in the same manner as heater 130 is affixed in the groove therefor in FIG. 3.

Alternatively, the tray can simply include a number of radial grooves similar to jumper portion 322, each having a heating element therein, a plurality of circumferentially extending grooves, or combinations thereof, which may be separately controlled, powered, or both, to allow the designer and the user of the tray 102 to optimize the temperature distribution across the substrate receiving portion 130 for the desired precursor to be used therewith.

Herein, the modular nature of the source architecture is capable on multiple configurations. In one aspect, it includes at least a tray and a cover or a base, wherein the tray if clamped, by an at least partially circumferentially extending clamp around a portion of the tray and a portion of the cover or base to connect them together. The tray is heated by an intrinsic or embedded heating element, by a heater extending circumferentially around the tray and operatively connected to the clamp, or both.

In another aspect, the tray heater includes at least a single length of heating material, which is embedded into the base of the tray. The single length can be configured in the form of a circumferential wave or sinusoidal-like pattern to extend along portions of the outer perimeter of the tray, portions of the inner perimeter of the tray, and locations intermediate the inner and outer perimeter of the tray. Alternatively, the heater can be embedded into the base of the tray and include a radially inner and a radially outer portion, electrically connected in series. Further, two different heaters, one disposed in a radially inner position as compared to the other can be employed, and separately controlled.

Additionally, the clamp is, in one aspect, configured to include at least one circumferential recess or pocket into which a heater can be secured to extend substantially around a tray when the clamp is connected to the tray. The clamp can include two circumferentially extending recesses, into each of which a heater can be secured, either a single continuous heater or two separate heaters.

In addition, the configuration of the source renders a readily serviceable source. For example, where the source includes at least one tray connected to at least one of a cover or base by a circumferentially extending clamp, the tray is serviced by simply unclamping it from the base of cover. Where a plurality of trays are stacked, a service person need simply unclamp the tray to be serviced from the tray or cover thereabove, to allow access to the internal precursor receiving surface thereof.

The modularity of the source allows for the creation of a source having one or more trays, where the number of trays can be optimized based on the material being used to evolve a gas in the source, the expected use requirements of the source, the available space within which the source can be housed, the time required to service the source, or other factors. Thus a source having only one, to a multitude, of trays is envisioned.

The use of individual tray heaters, embedded in a tray, surrounding a tray, or both, enables more uniform control of the tray temperature in the stack of trays in the stacked direction. Here, where the gas of each lower tray is passing through each tray thereover, where each tray heater generates the same heat amount, the upper trays will become hotter than the lower trays, and where the evolution rate of the gas from the solid or liquid precursor increases at higher temperature, the upper trays will require their source material replaced while source material (solid or liquid) remains in the lower trays. Thus, the user must service the source before all of the source material is used, or suffer a lower supply quantity of evolved source gas per unit of time. Here, by monitoring the temperature conditions at each tray, the individual heaters can be individually controlled to evolve different amounts of heat to generate the same temperature, within a tolerance range, in each tray. This results in a more uniform precursor use rate, allowing a longer in service time for each newly serviced source, and a more predictable time when the source need be serviced.

The source 100 as described herein provides the ability to use a single cover 106, a single base 104, and any number of trays 102 required to provide the surface area or precursor to be sublimated or vaporized into a carrier gas stream. Additionally the tray sizes can be varied, such that the evolver gas volume over each tray can vary in depth or diameter, or both, to meet a user's specific space and source generated gas delivery needs.

Additionally, where the gas source material, in other words the solid or liquid precursor, will evolve gas at room temperature, or at temperatures achievable using a heated carrier gas or surrounding heaters, the use of embedded heaters as shown in FIGS. 3, 13 and 14, as well as a heated clamp 280, can be avoided. In this case, the trays without internal heating elements 244 can be clamped together to provide the source.

While the foregoing is directed to embodiments of the present disclosure, other and further embodiments of the disclosure may be devised without departing from the basic scope thereof, and the scope of the invention is determined by the claims that follow.

1. A gas source, comprising:
a plurality of trays, each tray including a source receiving portion and an outer circumferential wall having an outer wall surface, the outer circumferential wall including at least one projecting flange thereon, each projecting flange having an outer circumferential flange surface and a second surface extending from the circumferential flange surface in the direction of the outer wall surface; and
a clamp, actuable between a circumferentially expanded condition and a circumferentially reduced condition, wherein, in the circumferentially reduced position, contact the second surface of the first tray and the second surface of the second tray.

2. The gas source of claim 1, wherein the first and second tray further comprise an annular adjacent tray facing surface extending radially inwardly from the outer circumferential flange surface.

3. The gas source of claim 2, wherein the annular adjacent tray facing surface is planar and extends normal to the outer circumferential flange surface.

4. The gas source of claim 3, further comprising a seal groove extending inwardly of the annular adjacent tray facing surface and having a seal ring therein.

5. The gas source of claim 1, further comprising a heater extending though the outer circumferential wall.

6. The gas source of claim 5, wherein the precursor receiving surface further includes a heater groove extending inwardly thereof, and the heater is disposed in the heater groove.

7. The gas source of claim 1, wherein the claim further comprises at least one heater therein.

8. The gas source of claim one, further comprising a sensor tube extending through the source receiving surface of at least one tray.

9. A gas source, comprising:
a single tray or a plurality of trays including a top cover and a bottom cover, each tray including a source receiving portion and an outer circumferential wall having an outer wall surface; and
a separate heater associated with each of the first tray and the second tray.

10. The source of claim 9, wherein the source receiving portion on each tray includes a heater groove, and each heater is a tubular structure disposed in inwardly of the heater groove.

11. The source of claim 9, wherein the outer circumferential surface further comprises at least one projecting flange thereon, each projecting flange having an outer circumferential flange surface and a second surface extending from the circumferential flange surface in the direction of the outer wall surface;
a clamp, actuable between a circumferentially expanded condition and a circumferentially reduced condition, wherein, in the circumferentially reduced position, contact the second surface of the first tray and the second surface of the second tray; and
a first heater disposed in the clamp and extending partially around the outer circumferential wall of one of the first tray and the second tray.

12. The source of claim 11, further comprising a second heater extending partially around the outer circumferential wall of one of the first tray and the second tray.

13. The source of claim 11, wherein the source receiving portion on each tray includes a heater groove, and each heater is a tubular structure disposed in inwardly of the heater groove.

14. The source of claim 9, wherein the outer circumferential surface further comprises at least one projecting flange thereon, each projecting flange having an outer circumferential flange surface and a second surface extending from the circumferential flange surface in the direction of the outer wall surface;
a base having a base outer wall having a base outer wall surface having a projecting flange thereon, the projecting flange having a base outer circumferential flange surface and a base second surface extending from the base outer circumferential flange surface in the direction of the outer wall surface; and
a clamp, actuable between a circumferentially expanded condition and a circumferentially reduced condition, wherein, in the circumferentially reduced position, the clamp contacts the first surface of the first tray and the base second surface.

15. The source of claim 9, further comprising a cover, the cover including a monitoring well extending therethrough.

16. A method of servicing a gas source, comprising;
providing a plurality of trays including at least a first tray and a second tray, each tray including a source receiving portion and an outer circumferential wall having an outer wall surface, the outer circumferential wall including at least one projecting flange thereon, each projecting flange having an outer circumferential flange surface and a second surface extending from the circumferential flange surface in the direction of the outer wall surface;
providing a clamp, actuable between a circumferentially expanded condition and a circumferentially reduced condition, wherein, in the circumferentially reduced position, contact the second surface of the first tray and the second surface of the second tray;
monitoring the condition of at least one tray; and
removing at least one tray from the plurality of trays by actuating the clamp from the circumferentially reduced condition to the circumferentially expanded condition while maintain any other clamp between adjacent trays in the circumferentially reduced condition.

17. The method of claim 16, further comprising supplying heat energy to at least the first tray and the second tray, wherein the heat energy provided to the first tray is different than the heat energy supplied to the second tray.

18. The method of claim 16, further comprising extending a sensor rod, having at least one sensor therein, through at least one of the first and the second tray.

19. The method of claim 17, further comprising supplying heat energy to at least the first tray and the second tray from a location exterior to the tray.

20. The method of claim 17, further comprising supplying heat energy to at least the first tray and the second tray from a location within the tray.

21. A gas source configured to evolve a gas from a precursor source material, comprising:
at least one tray, a base and a cover;
at least one circumferential clamp extending around a portion of the tray and one of the base and cover and releasable connecting the tray to one of the cover and the base.

22. The gas source of claim 21, wherein the clamp further comprises a heating element.

23. A gas source configured to evolve a gas from a precursor source material, comprising:
at least one tray, a base and a cover, the tray including a precursor receiving portion; and
a heater embedded in in the precursor receiving portion.
